(19) United States
(12) Patent Application Publication
(10) Pub. No.: US 2024/0174515 A1
(43) Pub. Date: May 30, 2024

(54) Systems of Getters for Microelectronics and Methods for Production Thereof

(71) Applicant: Mesoline Inc., Charlotte, NC (US)

(72) Inventors: Marnix P. Rebergen, Rotterdam (NL); Thomas C.R. Russell, Amsterdam (NL); Serhii Mytnyk, Capelle aan den IJssel (NL)

(73) Assignee: Mesoline Inc., Charlotte, NC (US)

(21) Appl. No.: 18/318,607

(22) Filed: May 16, 2023

Related U.S. Application Data
(60) Provisional application No. 63/364,793, filed on May 16, 2022.

(51) Int. Cl. B81C 1/00; B81B 7/00

(52) U.S. Cl. CPC B81C 1/00285; B81B 7/0038; B81B 2203/0315; B81C 2201/013; B81C 2203/0145

(57) ABSTRACT

Systems of getters for microelectronic devices and methods for micro-molding the getters are described. The getters comprising non-evaporable getter particles can be formed with a variety of nanoparticles and absorb various gas species to keep the microelectronic devices in desired working conditions. The micro-molded getters can be incorporated into various microelectronic devices.

### CROSS-REFERENCE TO RELATED APPLICATIONS

The current application claims the benefit of priority to U.S. Provisional Patent Application No. 63/364,793 entitled “Micro-Molding of Miniaturized Getters for Microelectronics” filed May 16, 2022. The disclosure of U.S. Provisional Patent Application No. 63/364,793 is hereby incorporated by reference in its entirety for all purposes.

### FIELD OF INVENTION

The present disclosure generally relates to getters for microelectronics; and more particularly to micro-molded non-evaporable getter s for use in microelectronics.

### BACKGROUND

Microelectronic devices often need a sealed package incorporating a getter to operate or to maintain their performance. Various gas species present and accumulated in microelectronic devices may lead to device failures due to conditions such as liquid condensation, metal corrosion, and/or sensing interference. Presence of the gas species can alter physical (such as pressure) and/or chemical environment for the devices. In order to maintain proper working conditions for microelectronic devices, getters can be included in device package.

Getter is a substance that can be used to maintain a vacuum or a constant gas composition inside a closed system by capturing and/or trapping gas molecules. Getters are passive devices which capture gas molecules through a combination of porous morphology and surface reactivity of the compositional materials.

### BRIEF SUMMARY

Systems and methods for getters comprising non-evaporable getter particles in various microelectronic devices are described.

One embodiment includes a microelectronic device or a microelectromechanical system (MEMS) device comprising:
a first substrate;
at least one functional element disposed on the first substrate; and
a getter system disposed on a second substrate in proximity to the at least one functional element, the getter system comprising a plurality of getters, each getter comprising a plurality of nanoparticles;
   wherein each of the plurality of getters has an aspect ratio between 0.05 and 10; and
   wherein the getter system covers a surface area less than or equal to 90% of the second substrate.

In another embodiment, the at least one functional element is etched into the first substrate.

In an additional embodiment, the plurality of getters forms a pattern selected from the group consisting of: a grid of lines, a plurality of the grids, a patch of connected shapes, and a plurality of the patches; wherein at least one of the connected shapes is selected from the group consisting of: a strip, a polygon, and an oval.

In a further embodiment, each of the getters has a width that is parallel to the second substrate between 10 microns and 500 microns, and a height that is perpendicular to the second substrate between 5 microns and 500 microns.

In another further embodiment, the first substrate and the second substrate are the same substrate that is a surface of a wafer.

In yet another embodiment, the second substrate is an intermediate layer deposited on the first substrate.

In an additional embodiment again, the second substrate is a surface of a capping wafer, and the first substrate is a surface of a wafer.

In a further yet embodiment, the second substrate is a surface of a cavity or a ledge located on a capping wafer, and the first substrate is a surface of a wafer.

In another further embodiment again, the second substrate is a surface of a cavity, and the first substrate suspends above the second substrate.

In yet another embodiment, the microelectronic or the MEMS device is selected from the group consisting of: a gyroscope, an accelerometer, an oscillator, a chip-scale atomic clock, a digital micro-mirror device (DMD), a spatial light modulator (SLM), a pressure sensor, a laser, an inertial measurement units (IMU), a microbolometer, a quantum device, and a superconducting qubit.

In another additional embodiment, the nanoparticles are selected from the group consisting of metal nanoparticles, metal-oxide nanoparticles, and metal alloy nanoparticles.

In yet another further embodiment, the nanoparticles comprise at least one element selected from the group consisting of: zinc, aluminum, yttrium, lanthanum, iron, molybdenum, niobium, tungsten, tantalum, manganese, titanium, zirconium, tin, nickel, chromium, cerium, platinum, gold, and cobalt.

In a further yet embodiment, the nanoparticles comprise at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxides.

In another further yet embodiment, the nanoparticles comprise at least one element selected from the group consisting of: zinc, aluminum, yttrium, lanthanum, iron, molybdenum, niobium, tungsten, tantalum, manganese, titanium, zirconium, tin, nickel, chromium, cerium, platinum, gold, and cobalt; and wherein the nanoparticles comprise at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxides.

In another additional embodiment again, the plurality of nanoparticles has an average diameter between 1 nm and 10 microns.

In a further yet embodiment, each getter further comprises a filler material; wherein the filler material controls a pore size of the getter.

In yet another embodiment, the getter system absorbs at least one of gas species selected from the group consisting of water vapor, hydrogen, oxygen, carbon monoxide, carbon dioxide, nitrogen and a volatile organic compound.

Another further yet embodiment comprises multiple substrates of getters and each substrate is configured to form onto a previous substrate.

In an additional embodiment again, the plurality of getters comprises a same material.

In a further embodiment again, the plurality of getters comprises different materials and each material is selected to capture a different gas species.

Another additional embodiment includes a method for micro-molding getters, comprising:
providing a substrate;
applying a stamp to the substrate, wherein the stamp comprises a plurality of channels disposed adjacent to the substrate;
dispensing a nanoparticle ink through the plurality of channels onto the substrate;
curing the nanoparticle ink in the plurality of channels to form a plurality of getters comprising the nanoparticle ink on the substrate;
removing the stamp;
sintering the plurality of getters; and
activating the plurality of getters.

In a further embodiment, the nanoparticle ink comprises nanoparticles selected from the group consisting of metal nanoparticles, metal-oxide nanoparticles, and metal alloy nanoparticles.

In an additional embodiment, the nanoparticle ink comprises at least one element selected from the group consisting of: zinc, aluminum, yttrium, lanthanum, iron, molybdenum, niobium, tungsten, tantalum, manganese, titanium, zirconium, tin, nickel, chromium, cerium, platinum, and cobalt.

In yet another embodiment, the nanoparticle ink comprises at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxides.

In a further yet embodiment, the nanoparticles comprise at least one element selected from the group consisting of: zinc, aluminum, yttrium, lanthanum, iron, molybdenum, niobium, tungsten, tantalum, manganese, titanium, zirconium, tin, nickel, chromium, cerium, platinum, and cobalt; and wherein the nanoparticles comprise at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxides.

In yet another embodiment again, the nanoparticle ink comprises nanoparticles with an average diameter between 1 nm and 10 microns.

In a further yet embodiment, the nanoparticle ink further comprises a filler material; wherein the filler material controls a pore size of the plurality of getters.

In another further embodiment, the stamp further comprises a recessed area such that the stamp avoids contact with a functional element on the substrate.

In yet another embodiment, the curing comprises contacting the nanoparticle ink with a source selected from the group consisting of: heat, an electromagnetic radiation, a xenon flash, an infrared radiation, an ultraviolet radiation, and a laser radiation.

In a further yet embodiment again, the sintering occurs at a temperature between 80° C. and 550° C.

In an additional embodiment again, the sintering occurs in an environment selected from the group consisting of: in air, in an inert gas, and in vacuum.

In another yet embodiment, the sintering comprises sintering the plurality of getters in an inert gas, followed by a second gas that chemically reduces surface material of the plurality of getters.

In yet another embodiment again, the activating occurs at a temperature between 80° C. and 550° C. in vacuum, in an inert gas, or in air.

In a further yet embodiment, the stamp further comprises a protrusion to form the plurality of getters in a cavity.

Additional embodiments and features are set forth in part in the description that follows, and in part will become apparent to those skilled in the art upon examination of the specification or may be learned by the practice of the disclosure. A further understanding of the nature and advantages of the present disclosure may be realized by reference to the remaining portions of the specification and the drawings, which forms a part of this disclosure.

### BRIEF DESCRIPTION OF THE DRAWINGS

The description and claims will be more fully understood with reference to the following figures and data graphs, which are presented as exemplary embodiments of the invention and should not be construed as a complete recitation of the scope of the invention.

FIGS. 1A-1C illustrate micro-molding stamps in accordance with an embodiment of the invention.

FIG. 2 illustrates a process for fabricating getters in accordance with an embodiment of the invention.

FIG. 3 illustrates a micro-molded getter deposited on a substrate in accordance with an embodiment of the invention.

FIG. 4 illustrates a scanning electron microscopy micrograph of a hydrogen getter in accordance with an embodiment of the invention.

FIGS. 5A-5D illustrate a micro-molded getter integrated with a microelectronic device in top view and in cross section in accordance with an embodiment of the invention.

FIGS. 6A-6B illustrate a micro-molded getter deposited onto a digital-micromirror device in top view and in cross section in accordance with an embodiment of the invention.

FIG. 7 illustrates a micro-molding stamp with recesses in accordance with an embodiment of the invention.

FIG. 8A illustrates a micro-molding stamp for forming getters in a cavity in accordance with an embodiment of the invention.

FIG. 8B illustrates micro-molded getters deposited onto the lid of microelectronic devices in accordance with an embodiment of the invention.

FIG. 9A illustrates a micro-molding stamp for forming getters in a cavity under functional elements of microelectronic devices in accordance with an embodiment of the invention.

FIG. 9B illustrates micro-molding getters formed with getter materials in cavities or recesses in the substrate in accordance with an embodiment of the invention.

### DETAILED DESCRIPTION OF CERTAIN EMBODIMENTS

Getter in microelectronic devices can absorb unwanted gas species and maintain performance of the devices. Presence of gas species such as water vapor, hydrogen, oxygen, volatile organic compounds can lead to device failures due to liquid condensation, metal corrosion or oxidation, sensing interference, and so on. Getters can maintain the desired pressure (such as vacuum) and/or gas composition for microelectronic devices by capturing and/or trapping gas molecules.

Microelectromechanical systems (MEMS) such as mechanical or optoelectronic devices containing high frequency mechanical components rely on vacuum packaging to maintain their performance. Presence of gas molecules in the device package can have a damping effect, reducing the device performance. For microelectronic or MEMS devices such as pressure sensors or micro-bolometers, a specific gas composition need to be maintained within the device package to ensure the lifetime of sensitive components. Controlling the desired gas composition can prevent condensation of water vapor, corrosion or hydrogen diffusion of and/or into sensitive materials, or prevent radiation absorption by residual gas inside the device. Certain MEMS pressure sensors rely on a fixed gas pressure or vacuum being maintained within a cavity inside of the device.

Getters can vary in structures and/or materials. Some getters comprise a porous structure. The porous morphology and surface reactivity of the compositional materials can capture gas molecules passively. Some getters can be deposited as a film. Conventional approaches for integrated getters into microelectronic packaging rely on the deposition of thick films of the getter material. Deposition techniques for thick films of getter material typically offer a minimum feature size of about 50 microns, with film thicknesses from a few microns up to hundreds of microns. However, microelectronic devices manufactured on wafers often have limited and constrained space. In addition, thick-film deposition methods can damage sensitive components on the wafer device. These limitations represent drawbacks of using conventional thick-film deposition approaches to deposit getters in microelectronic devices. One approach incorporated the getter onto a second capping wafer or lid containing recesses which is then bonded to the device wafer or die containing the electronic devices. (See, e.g., EP Patent No. EP1957395B1, U.S. Pat. No. 8,105,860B2, the disclosures of which are herein incorporated by reference) However, such approaches may impose restrictions on the proximity of the getter to other important components of the device which should be maintained in vacuum, which is particularly relevant for mechanical devices such as high q-factor resonators. For some microelectronic devices, such as for digital micro-mirror devices or microbolometers, the capping wafer approach cannot be used, since the package itself need to be transparent to electromagnetic radiation.

An alternative to thick-film getter deposition methods is thin-film deposition technique. Thin-film deposition process can dispose getters in fine lines onto the device wafer, with widths down to several microns. However, these deposition methods can be limited in layer thickness, which limits the thickness of the getter and the amount of gas molecules that can be absorbed, thereby limiting their ability to maintain a constant gas composition inside the device packaging over time.

Non-evaporable getters (NEGs) can be deposited and/or applied in solid form, such as (but not limited to) as particles. NEGs differ from getters that are evaporated as a thin film. In this disclosure, getters refer to non-evaporable getters (NEGs) and/or structures comprised of non-evaporable getters, unless specifically stated otherwise.

Micro-molding is a manufacturing process that can produce small and high-precision parts and components with micron tolerances. The process can start by creating a mold that has a cavity in the shape of the part desired. Micro-molding can use a flexible stamp together with inks to pattern microscopic features onto a substantially flat substrate. (See, e.g., U.S. Patent Publication No. US20210381994A1, the disclosure of which is herein incorporated by reference.)

In many embodiments, getters for microelectronic and/or MEMS devices can be formed using micro-molding processes. Micro-molding processes can increase getter performance, improve manufacturability, and reduce device footprint, compared to conventional manufacturing processes. Getters can be formed using micro-molding stamps with various types of ink comprising particles and/or nanoparticles. Micro-molded getters constructed from various species of nanoparticles have features that are well-defined, miniaturized, and with fine-lines, compare to thick film getters or thin film getters.

Getters in accordance with many embodiments can be used in various microelectronic and/or MEMS devices including (but not limited to) gyroscopes, accelerometers, oscillators, chip-scale atomic clocks, digital micro-mirror devices (DMDs), spatial light modulators (SLMs), pressure sensors, lasers, inertial measurement units (IMUs), microbolometers, and/or quantum devices such as superconducting qubits. In this disclosure, microelectronic devices and/or devices refer to the above listed microelectronic and/or MEMS devices, unless specifically stated otherwise.

In several embodiments, getters comprising NEG particles can be deposited via micro-molding directly onto substrates such as (but not limited to) wafers of microelectronic devices. The getters can have at least one dimension such as (but not limited to) width and/or height ranging from about 1 micron to about 100 mm; or from about 1 micron to about 50 mm; or from about 1 micron to about 10 mm; or from about 1 micron to about 1 mm; or from about 1 micron to about 500 microns; or from about 5 microns to about 500 microns; or from about 10 microns to about 500 microns; or from about 1 micron to about 100 microns; or from about 1 micron to about 50 microns; or from about 1 micron to about 10 microns.

Many embodiments control porosity of getters during micro-molding processes. In some embodiments, controlling nanoparticle geometries and/or compositions during micro-molding can control the porosity of the deposited getters. Some embodiments select nanoparticles of specific geometries. Several embodiments incorporate filler materials in the ink that can result in inert cavities in micro-molded getters.

Getters in accordance with some embodiments can have various geometries. In various embodiments, getters can have a large reactive surface area for capturing gas molecules, while retaining a small footprint on the microelectronic devices. In certain embodiments, micro-molding deposited getters can cover less than about 90% of the surface area of the device; or less than about 80% of the surface area of the device; or less than about 70% of the surface area of the device; or less than about 60% of the surface area of the device; or less than about 50% of the surface area of the device; or less than about 40% of the surface area of the device; or less than about 30% of the surface area of the device; or less than about 20% of the surface area of the device; or less than about 10% of the surface area of the device; or less than about 5% of the surface area of the device.

In many embodiments, getters can absorb gas species present in microelectronic devices such as (but not limited to) water vapor, hydrogen, oxygen, carbon monoxide, carbon dioxide, nitrogen and/or volatile organic compounds. Examples of volatile organic compounds include (but are not limited to) alcohols, ketones, esters, hydrocarbons, and amines. Getters can be made of the same and/or different materials that are selected to absorb the desired gas species in accordance with several embodiments.

### Micro-Molding

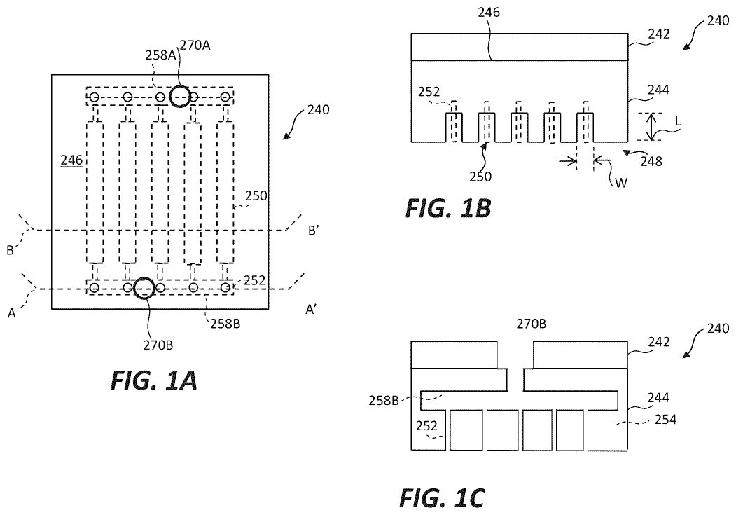

Many embodiments implement micro-molding stamps to integrate getters in various microelectronic devices. Getters comprising NEG particles can be deposited using the stamps. A micro-molding stamp in accordance with an embodiment of the invention is illustrated in FIGS. 1A through 1C. FIG. 1A illustrates a top view of the stamp. FIG. 1B shows a cross section view of the BB′ plane in FIG. 1A. FIG. 1C shows a cross section view of the AA′ plane in FIG. 1A. Micro-molding stamp 240 comprises a mold layer 244 having a support side 246 and a channel side 248. A support layer 242 is disposed in contact with support side 246. Support layer 242 can be more rigid than mold layer 244 to provide dimensional stability to mold layer 244 and enable improved resolution for structures formed by micro-molding stamp 240. Mold layer 244 can comprise a plurality of microscopic grooves and/or channels 250 disposed on the channel side 248 in mold layer 244. The channels can have an average width W ranging from about 1 micron to about 500 microns; or from about 1 micron to about 250 microns; or from about 1 micron to about 100 microns; or from about 1 micron to about 50 microns; or from about 1 micron to about 10 microns. The channels can have an average height L ranging from about 1 micron to about 500 microns; or from about 1 micron to about 250 microns; or from about 1 micron to about 100 microns; or from about 1 micron to about 50 microns; or from about 1 micron to about 10 microns. The width W and height L of the channels may be the same or may be different. During micro-molding processes, the plurality of channels can be aligned with the substrate via features such as (but not limited to) alignment marks. The alignment can occur before contacting the stamp with the substrate.

Inlet ports 270A embedded in the support layer 242 can be connected to the plurality of channels and/or grooves 250. Each of the inlet ports is connected to at least one of the channels. Inlet ports can be connected with syringes and/or pumps (not shown) to pump inks into the channels 250. Ink comprising getter materials can be pumped through inlet ports 270A into one or more ink reservoirs 258A embedded in the mold layer 244. The ink reservoirs 258A connect to one or more grooves 250 via one or more through holes 252. To facilitate ink flow through the grooves 250, the plurality of grooves 250 are connected via through-holes 252 in the mold layer to one or more outlet reservoirs 258B which are in turn connected to one or more outlet ports 270B. The outlet reservoirs 258B can be distinct. Ink can flow through the channels and/or grooves by capillary action and/or applied pressure to the inlet ports. In some embodiments, ink reservoirs 258A and/or 258B may comprise various layouts, geometries, and/or designs to facilitate the distribution of ink to different layouts of the grooves/channels 250 or to supply different inks/materials to different sets of grooves. Vacuum can be applied to the outlet ports to facilitate the flow.

Mold layer 244 can comprise an elastomeric material including (but not limited to) polydimethylsiloxane, polyurethane, room-temperature vulcanizing silicone rubber, or photocurable rubbers cast and cured on a defined master, for example a master structure micromachined into a silicon wafer, or a polymer structure fabricated onto a substrate such as a silicon wafer, for example by means of photolithography. Support layer 242 can comprise a more rigid material than mold layer 244, for example glass, silicon, polymethylmethacrylate, polycarbonate, or quartz and can be thinner than mold layer 244. In some embodiments, mold layer 244 can be reinforced by incorporation of nanoparticles into the elastomeric material, or by the inclusion of a fiber mesh composed of including (but not limited to) glass, steel, carbon, or nylon. Support layer 242 can comprise a more rigid material including (but not limited to) glass, than mold layer 244, and can be thinner than mold layer 244.

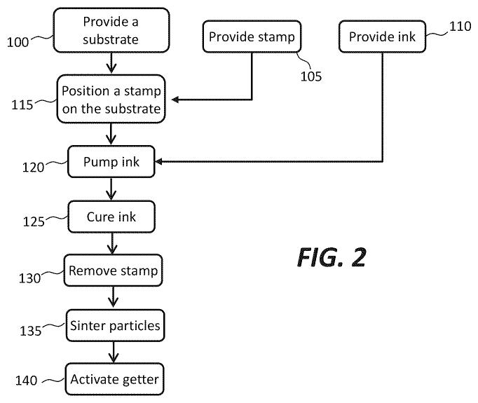

FIG. 2 illustrates a micro-molding process to form getters in accordance with an embodiment. The fabrication process starts by providing (100) a substrate. The substrate can be any form of a substrate containing microelectronic devices. Examples of the substrate include (but are not limited to) wafer, silicon wafer, crystalline silicon, and/or doped silicon. Through the methods described here getters may be micro-molded onto a substrate surface. In some embodiment the substrate surface may be part of a chip on which a single microelectronic circuit or device is integrated. In other embodiments substrate surface may comprise a wafer containing multiple, possibility distinct, microelectronic circuits or devices. In further embodiments micro-molded getters are integrated onto a surface or die which is then integrated into the packaging of a microelectronic device which is comprised of multiple components or dies, for example a capping wafer or packaging lid which is bonded in vacuum to the device wafer to hermetically seal the microelectronic device.

Provide (105) a stamp and position (115) the stamp on the substrate. The stamp can be a micro-molding stamp. The stamp can be used to dispose getters on the substrate. Mold layer of the micro-molding stamp can be disposed in contact with (for example in conformal contact with) the substrate surface of the substrate.

Provide (110) an ink and pump (120) the ink into the stamp. The ink can contain getter materials including (but not limited to) NEG materials to be deposited on to the substrate. The ink can be a nanoparticle ink comprising a suspension of nanoparticles in a liquid solvent, and/or a dispersant, and/or with other additives. The nanoparticles comprise getter materials. The fraction of weight or volume of getter materials compared to the weight or volume of other components (such as solvents, dispersants, and other additives), may range between about 1% and about 95%; or between about 10% and about 60%. Additives can be added to the ink to achieve desired solubility and/or viscosity and/or density and/or surface energy. The nanoparticles may have an average diameter ranging between about 1 nm and about 10000 nm; or between about 1 nm and about 10 nm; or between about 10 nm and about 300 nm; or between about 300 nm and about 1000 nm; or between about 1000 nm and about 10000 nm.

The nanoparticle ink can be pumped and/or dispensed through inlet ports of the stamp. As nanoparticles move through the channels, solvent in nanoparticle ink can diffuse into the mold layer so that the nanoparticles become tightly packed in the channels. Substantial wetting of the channels by the ink can be important to achieving the desired shape and facilitating fast extraction of the solvent. In some embodiments, micro-molding stamps with one or more ink distribution layers comprising a set of microchannels can route ink from inlet and outlet ports to channels and/or grooves.

The process can be accelerated by curing (125) the ink. The ink can be cured within the microchannels at temperatures ranging from about 20° C. to about 25° C.; or greater than about 25° C. The curing process in accordance with some embodiments includes (but not limited to) exposure the nanoparticle ink to heat, and/or to electromagnetic radiation. Examples of electromagnetic radiation include (but are not limited to) a xenon flash, infrared radiation, ultraviolet radiation, or laser radiation. During the curing processes, the solvent of the nanoparticle ink can be driven off from the nanoparticle ink and/or the mold layer. In some embodiments, the driven off solvent can be absorbed (at least in part) by the mold layer of the micro-molding stamp. In some embodiments, curing may not be necessary to form getters.

Remove (130) the stamp once getters are deposited. The getters can be free-standing structures on the substrate without having supporting structures and/or walls. The getters can have the patterns and geometries of the microchannels.

Sinter (135) the particles. Substrate containing the getter structures can be sintered to improve mechanical stability and/or to remove organic residuals from the getter materials. Sintering and/or fusing nanoparticles in accordance with certain embodiments can be accomplished by exposing nanoparticles to heat, UV radiation, laser radiation, or electromagnetic radiation. In a number of embodiments, sintering processes can be performed within a protective atmosphere including (but not limited to) in inert gases, in reactive gasses, or in vacuum in order to protect and/or prepare the surface of the getters. Examples of inert gases include (but are not limited to) nitrogen, helium, argon, hydrogen, and carbon dioxide. Sintering can be carried out at temperatures from about 80° C. to about 700° C.; or from about 80° C. to about 600° C.; or from about 80° C. to about 550° C.; or from about 80° C. to about 500° C.; or from about 80° C. to about 100° C.; or from about 100° C. to about 200° C.; or from about 200° ° C. to about 500° C.; or from about 500° C. to about 700° C.

Activate (140) getters once they are formed. In some embodiments, getters can be activated in order to release adsorbed molecules from its surface. Activation can be achieved by heating getter materials in vacuum at a pressure between about 50 millibar and about 10×10\hat{ }-9 (10e-9) millibar. In many embodiments, activating processes can be performed in an atmosphere including (but not limited to) in inert gases, in vacuum, or in air. Examples of inert gases include (but are not limited to) nitrogen, helium, argon, hydrogen, and carbon dioxide. Activation can be carried out at temperatures from about 80° C. to about 700° C.; or from about 80° C. to about 600° C.; or from about 80° C. to about 550° C.; or from about 80° ° C. to about 500° C.; or from about 80° C. to about 100° C.; or from about 100° C. to about 200° C.; or from about 200° C. to about 500° C.; or from about 500° ° C. to about 700° C.

In a number of embodiments, micro-molded getters can be activated during a bonding process. Some embodiments activate getters during the wafer to wafer bonding step which is part of the device packaging process. Bonding techniques may include (but are not limited to) glass frit bonding, anodic bonding, Al—Ge, Au—Si bonding (brazing), eutectic bonding. Bonding processes can be performed at temperatures between about 150° C. and about 550° C.

As can be readily appreciated, getters of different structures can be formed by using microscopic channels and/or grooves of different geometries. Getters of different material compositions can be formed by using different inks. Multiple layers of getters can be formed using repeated processes described above. Multi-layer getters can be formed with the same or different materials, and/or having the same or different geometries.

Although FIGS. 1A through 2 illustrate micro-molding stamps and micro-molding fabrication process of getters, any systems and methods can be utilized as appropriate depending on the specific requirements of the given application.

### Getters

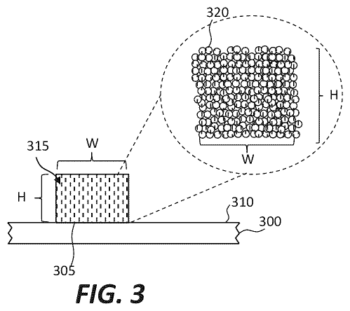

Getters of various structures, geometries, material compositions can be incorporated with various types of microelectronic devices. In many embodiments, getters formed with NEG particles can have a large surface area to react with gas molecules and/or desired porosity to absorb gas molecules. FIG. 3 illustrates a cross-section of a micro-molded getter in accordance with an embodiment. Getter 315 can be deposited via micro-molding onto one surface 310 of a substrate 300, having a contact area or footprint 305. The getter 315 can have width W and height H. The width W can range from about 1 micron to about 500 microns; or from about 10 microns to about 300 microns; or from about 1 micron to about 250 microns; or from about 1 micron to about 100 microns; or from about 1 micron to about 50 microns; or from about 1 micron to about 10 microns. The height H can range from about 1 micron to about 500 microns; or from about 10 microns to about 300 microns; or from about 1 micron to about 250 microns; or from about 1 micron to about 100 microns; or from about 1 micron to about 50 microns; or from about 1 micron to about 10 microns. The width W and height L of the channels may be the same or may be different.

In some embodiments, getters can have a high aspect ratio in order to reduce the footprint and/or size of getters on microelectronic devices. In several embodiments, micro-molded getters can have aspect ratios between about 0.05 and about 50; or between about 0.1 and about 40; or between about 0.1 and about 30; or between about 0.1 and about 20; or between about 0.1 and about 10, where the width W is less than the length L.

Getter 315 can comprise nanoparticles 320. In some embodiments, micro-molded getters comprise at least one material including (but not limited to) micro-porous silica, meso-porous silica, silicon dioxide, porous glass, activated carbon, synthetic zeolites, natural zeolites (such as, molecular sieves 3A, 4A, 5A, 10X, 13X), aluminosilicate minerals and clays (such as montmorillonite, halloysite), metal oxide, copper oxide, palladium oxide, platinum oxide, and iron oxide. In several embodiments, micro-molded getters comprise metals, metal alloys, and/or metal oxides including at least one metal element including (but not limited to) aluminum (Al), yttrium (Y), lanthanum (La), iron (Fe), molybdenum (Mo), tantalum (Ta), tungsten (W), niobium (Nb), manganese (Mn), chromium (Cr), titanium (Ti), zirconium (Zr), nickel (Ni), zinc (Zn), tin (Sn), cerium (Ce), palladium (Pd), cobalt (Co), platinum (Pt), and gold (Au). In some embodiments, getters can be formed using inks and/or suspension solutions loaded with nanoparticles containing the aforementioned materials or combinations thereof. In certain embodiments, nanoparticles comprise at least one metal, metal alloy, and/or metal oxide of aforementioned materials or combinations thereof.

In various embodiments, multiple getters of different or same materials may be micro-molded onto a single device in one or more steps by using different sets of microscopic grooves. Each set of the microscopic grooves can be used to pattern a different or the same material.

In further embodiments, multiple layers of getter material may be deposited onto previously micro-molded getters to form a multi-layer getter structure which can improve sorption performance. This may be achieved by performing multiple iterations of the micro-molding process, such as (but not limited to) using different inks and stamps. Some embodiments may use thin-film deposition methods such as evaporation or sputtering to deposit some of the layers.

Getters 315 may contain various structures and topographic steps. In some embodiments, getters may be deposited around and/or onto structures and/or surfaces of microelectronic devices or onto a wafer containing microelectronic devices. In some embodiments, topographic steps may include constructing conductor traces and/or etched trenches.

In further embodiments, nanoparticle packing density and/or pore size can be controlled. Some embodiments select nanoparticles of specific geometries for the ink. Examples of nanoparticle geometries include (but are not limited to), tubes, nanowires, sheets, cubes, rods, platelets, cubes, various polyhedral and any combinations thereof. Several embodiments incorporate filler materials such as polymers into the ink. After sintering, the filler materials can form inert cavities or domains within micro-molded getters. In some embodiments, micro-molded getters may have an average pore size and/or cavity size ranging from about 0.1 nm to about 500 nm; or from about 1 nm to about 400 nm; or from about 5 nm to about 300 nm; or from about 5 nm to about 200 nm; or from about 1 nm to about 100 nm; or from about 0.1 nm to about 50 nm; or from about 0.1 nm to about 10 nm.

In certain embodiments, getters can be micro molded in specific shapes, patterns, and/or structures to increase the effective surface area of the getter. Getters can have a shape of: a column, a cube, a strip, a patch, a cuboid, a dot, a polyhedron, a sphere, a polygon, an oval, a square, a triangle, a tube, a cylinder, and any combinations thereof. Getters can have flat surfaces. In some embodiments getters such shapes or patches are disposed in contact to form a single connected getter. A plurality of getters can be arranged in arrays, in grids, in parallel lines, and/or randomly. A distance between getters arranged in grids can vary from about 10 microns to about 10 mm; or from about 10 microns to about 100 microns; or from about 100 microns to about 200 microns; or from about 200 microns to about 300 microns; or from about 300 microns to about 400 microns; or from about 400 microns to about 500 microns; or from about 500 microns to about 600 microns; or from about 600 microns to about 700 microns; or from about 700 microns to about 800 microns; or from about 800 microns to about 900 microns; or from about 900 microns to about 1 mm; or from about 1 mm to about 10 mm.

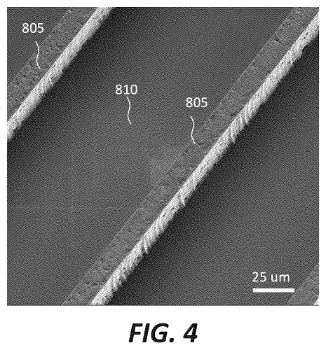

FIG. 4 illustrates a scanning electron microscope (SEM) image of getters in accordance with an embodiment. FIG. 4 shows a top-down image of a grid of high-aspect ratio hydrogen getters 805 on a silicon chip 810 of a microelectronic device. The getters 805 are micro-molded onto the surface of the silicon chip 810.

Although FIG. 3 through FIG. 4 illustrate micro-molded getters, any getter systems of various structures, geometries, and/or layouts can be utilized as appropriate depending on the specific requirements of the given application.

In various embodiments, getters can be incorporated into microelectronic devices and/or MEMS devices. Examples of microelectronic devices include (but are not limited to): optical devices, microbolometers, opto-electronic devices, infrared imaging sensors, and infrared spectrophotometers. Examples of MEMS devices include (but are not limited to): accelerometers, pressure sensors, gyroscopes, digital micromirror devices (DMDs), spatial light modulators (SLMs), and inertial measurement units (IMUs). Getters can maintain the desired environmental conditions such as low humidity, a (partial) vacuum, low volatile organic concentration, or low hydrogen concentration, within the sealed package of these microelectronic devices. Getters can surround active areas of microelectronic devices completely and/or partially. Getters maintain the working environment in a passive way such that they do not absorb, reflect, refract or affect light incident upon or emitted by the optical element. High-aspect ratio getters deposited via micro-molding can have minimal effect on the footprint of the device.

Microelectronic devices may contain at least one functional element (also referred as functional feature, or feature). Functional elements can be (but not limited to): sensing elements, pressure sensor membranes, resistors, capacitors, inductors, magnets, electrodes, movable micromirrors, bolometric pixels, photodetectors, MEMS actuators, MEMS resonators, piezo elements, ultrasound transducers, application-specific integrated circuits (ASICs), qubits, microprocessors, radio frequency transducers, and actuator components, or arrays thereof. Correct operation of functional elements may rely on specific gas compositions and/or vacuum in the environment. Incorporating getters into microelectronic devices can control the working environment of the functional elements to ensure their accurate operations. Micro-molded getters may include strain reliefs, such as (but not limited to) bends, to prevent thermal stress from causing damages to the functional elements during thermal expansion or contraction.

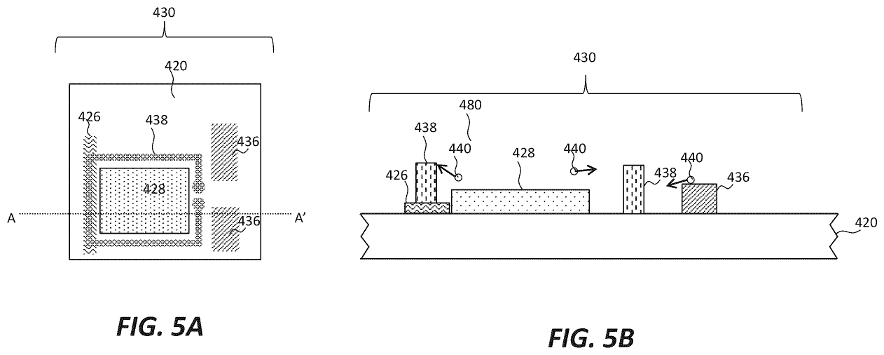

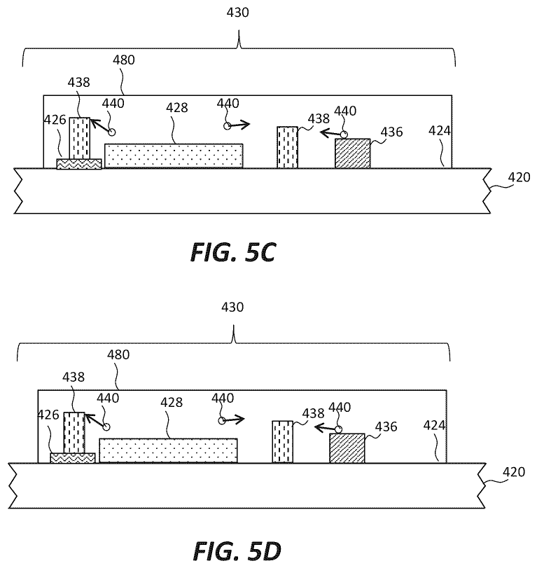

FIGS. 5A and 5D illustrate a microelectronic device with micro-molded getter deposited surrounding a functional element in accordance with an embodiment. FIG. 5A shows a top view of the device. FIG. 5B shows a cross sectional view of the device along the AA′ plane. FIG. 5C shows a cross sectional view of the device along the AA′ plane with an alternative getter structure. FIG. 5D shows a cross sectional view of the device along the AA′ plane with another alternative getter structure.

The microelectronic device 430 includes a substrate 420. Functional elements 428 can be formed on the substrate 420. Functional elements can be any types of and/or a portion of sensors, actuators, and any combinations thereof. Getters 438 can be micro-molded in proximity to and/or surrounding the functional elements 428. The distance between the getters 438 and the functional elements 428 can be from about 10 microns to about 500 microns; or from about 10 microns to about 400 microns; or from about 10 microns to about 300 microns; or from about 10 microns to about 200 microns; or from about 10 microns to about 100 microns; or from about 10 microns to about 50 microns; or from about 10 microns to about 40 microns; or from about 10 microns to about 30 microns; or from about 10 microns to about 20 microns.

The microelectronic device 430 can include auxiliary elements 436 on the substrate 420. Examples of auxiliary elements can be (but not limited to): sensing elements, pressure sensor membranes, resistors, capacitors, inductors, magnets, electrodes, movable micromirrors, bolometric pixels, photodetectors, MEMS actuators, MEMS resonators, piezo elements, ultrasound transducers, application-specific integrated circuits (ASICs), microprocessors, radio frequency transducers, and actuator components, or arrays thereof. Functional elements 428 and/or auxiliary elements 436 can emit gas molecules 440. Gas molecules 440 can be captured by getters 438 surrounding the functional elements 428, such that the efficiency of the gas capturing process can be increased. As can be seen in the cross section view of FIG. 5B, the functional elements 428, getters 438, and auxiliary elements 436 can be deposed within a hermetically sealed package 480.

In some embodiments, micro-molded getters 438 can be disposed onto an intermediate layer 426. The intermediate layer 426 is between the substrate surface 424 and the getters 438. In several embodiments, intermediate layers can comprise such as (but not limited to) ceramics and/or oxide materials. Intermediate layers can improve adhesion of micro-molded getter to the substrate and/or act as a diffusion barrier between the getter material and semiconducting substrate. In various embodiments, intermediate layers can be created via micro-molding processes or thin-film deposition techniques.

FIG. 5C shows intermediate layers 426 deposited between getters 438 and the substrate 420. FIG. 5D shows intermediate layers 426 deposited between only part of getters 438 and the substrate 420.

In many embodiments, multiple discrete getter can be micro-molded onto the same substrate. Getters can be separated by a distance. Distance between two adjacent getters can be the same or different. Adjacent getters can have a distance of less than or equal to about 10 microns; or from about 5 microns to about 10 microns; or from about 5 microns to about 50 microns; or from about 5 microns to about 100 microns; or from about 5 microns to about 150 microns; or from about 5 microns to about 200 microns; or from about 5 microns to about 250 microns; or from about 5 microns to about 300 microns; or from about 5 microns to about 350 microns; or from about 5 microns to about 400 microns; or from about 5 microns to about 450 microns; or from about 5 microns to about 500 microns.

Micro-molding methods can deposit getter structures of high precision in accordance with several embodiments. In some embodiments, the height of getters can be adjusted to maximize the volume of the getter material without interfering with the package. In certain embodiments, getters can have a height less than or equal to about 1 micron below the package height when deposited via micro-molding and when the package has a height up to about 10 microns.

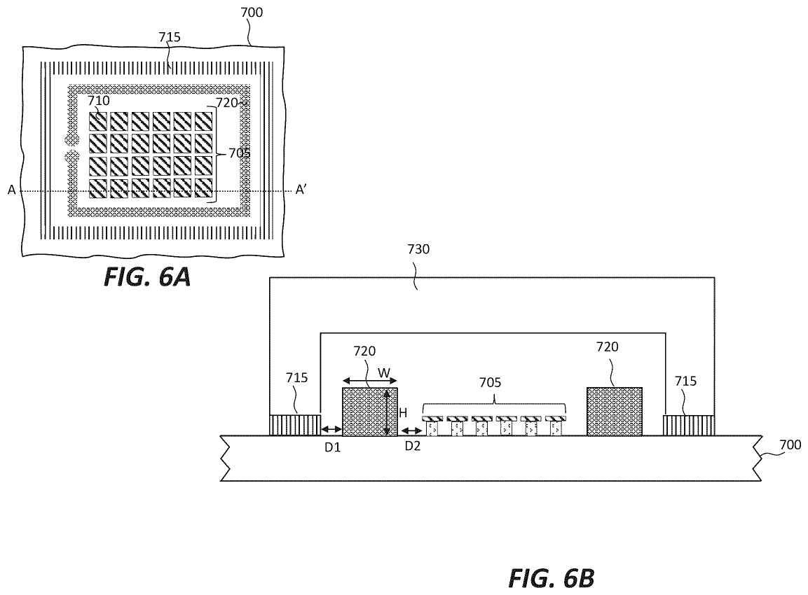

Getters can be incorporated onto various types of microelectronic devices including (but not limited to) optical devices and/or MEMS devices such as microbolometers, opto-electronic devices, infrared imaging sensors, infrared spectrophotometers, DMDs, SLMs, accelerometers, pressure sensors, gyroscopes, and IMUs. FIGS. 6A and 6B illustrate a microelectronic device incorporated with getters in accordance with an embodiment. FIG. 6B shows a cross sectional view of the AA′ plane of FIG. 6A. The microelectronic device can be a digital micromirror device or spatial light modulator. The microelectronic device is deposited on a substrate 700. The active area of the device comprises an array 705 of movable mirrors 710. The array 705 can have a shape of a square or a rectangle. At least one dimension of the array can range between about 1 mm and about 50 mm. Getters (or getter materials) 720 is deposited by micro-molding NEG nanoparticles onto the area surrounding mirrors array 705 but within a bond line 715. The bond line 715 defines an area where the device is mechanically joined to the lid 730 to provide a hermetically sealed device package.

In some embodiments, getters 720 may be deposited in close proximity to the bond line 715 at a distance D1 between about 10 microns and about 500 microns; or between about 10 microns and about 400 microns; or between about 10 microns and about 300 microns; or between about 10 microns and about 200 microns; or between about 10 microns and about 100 microns; or between about 10 microns and about 50 microns. The distance D2 between the array of mirrors 705 and getters 720 ranges between about 10 microns and about 500 microns; or between about 10 microns and about 400 microns; or between about 10 microns and about 300 microns; or between about 10 microns and about 200 microns; or between about 10 microns and about 100 microns; or between about 10 microns and about 50 microns.

In various embodiments. The width W of micro-molded getters can range between about 10 microns and about 500 microns; or between about 20 microns and about 400 microns; or between about 30 microns and about 300 microns; or between about 30 microns and about 100 microns; or between about 30 microns and about 50 microns. The height H of getters can range between about 1 micron and about 100 microns; or between about 5 microns and 50 microns; or between about 5 microns and about 25 microns; or between about 5 microns and 10 microns. Height and width may vary along the length of the getter. Micro-molded lines may be curved or straight. Micro-molded getters may comprise a singularly molded pattern, or comprise multiple, discrete sections which are molded separately.

Although FIGS. 5A through 6B illustrate getters incorporated with microelectronic devices, any types of microelectronic devices and suitable getter systems can be utilized as appropriate depending on the specific requirements of the given application.

Several embodiments implement micro-molding stamps with recessed areas for getter fabrication. Certain areas of some microelectronic devices would need to avoid direct contact with the micro-molds and/or stamps during micro-molding processes in order to avoid mechanical damages and/or chemical contamination to sensitive components. Those areas may contain functional elements and/or auxiliary elements such as (but not limited to) optically or chemically sensitive structures, and mechanical components. Examples of optically or chemically sensitive structures include (but are not limited to) micro-mirrors, pixels which are part of DMDs or SLMs. Examples of mechanical components include (but are not limited to) cantilevers, resonators, and mechanical actuators which are part of MEMS devices.

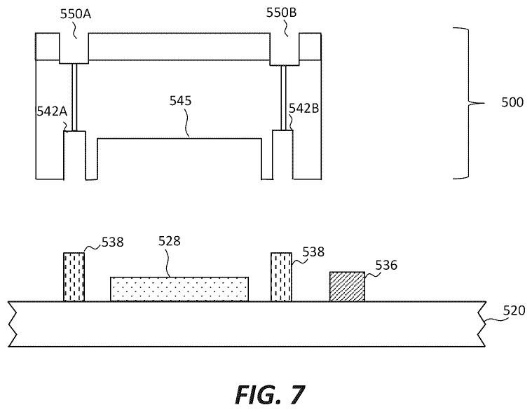

A micro-molding stamp with recessed areas in accordance with an embodiment is illustrated in FIG. 7. Micro-molding stamps 500 have recessed areas 545 in order for the stamp 500 not be in contact with sensitive microelectronic elements during micro-molding. Stamps 500 includes channels 542A and 542B to deposit getter materials. Inlet ports 550A can inject inks into the channels. Residual inks can be removed through outlet ports 550B. During micro-molding process, stamps 500 are brought in contact with the substrate 520 of microelectronic devices. Recessed areas 545 prevent the stamp 500 to be in direct contact with the functional elements 528 on the substrate 520, while getters 538 are being formed on the substrate 520. Auxiliary elements 536 are also not in contact with the stamp 500.

In some embodiments, recessed areas 545 can be included in stamps 500 to reduce peel-off force. Peel-off force is proportional to the contact area and can be experienced by the device or substrate during stamp removal from the substrate surface 520. Peel-off force can also be experienced by any components or areas of that may be in contact with stamps.

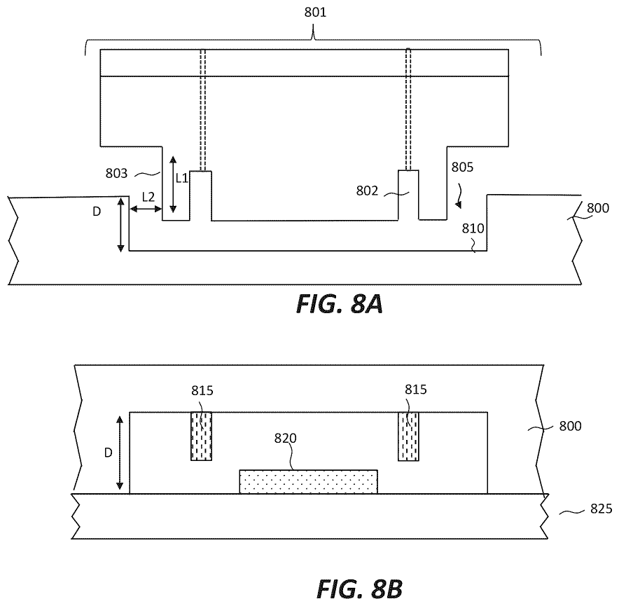

Getters in accordance with various embodiments can be deposited in different positions of microelectronic devices. In some embodiments, micro-molded getters can be deposited within a cavity of microelectronic devices. The cavity can have a substantially flat bottom surface. The cavity can be embedded as a part of microelectronic devices or their substrates, or as a part of lids, or as a part of capping wafers. In several embodiments, getters may be deposited onto a ridge and/or ledge situated inside the cavity which is between the surface of the substrate and the bottom of the cavity. A micro-molding stamp to print within a cavity in accordance with the invention is illustrated in FIG. 8A. FIG. 8A shows a cross section of a micro-molding stamp 801 that can be used to print getters within a cavity 805. The cavity 805 is embedded in a substrate 800. The micro-molding stamp 801 contains a protrusion 803 with a depth L1 greater than the cavity depth D. The protrusion 803 incorporates micro-molding grooves and/or channels 802 and fits into the cavity 805. FIG. 8B illustrates integration of microelectronic devices with getters micro-molded in a cavity in accordance with an embodiment, for example by micro-molding getters onto a capping lid or capping wafer. FIG. 8B shows the substrate with cavity and micro-molded getters 815, after bonding to a device wafer 825 containing a functional element 820. In various embodiments, multiple cavities present on the same substrate may have getter elements micro-molded using a single stamp with a plurality of such protrusions.

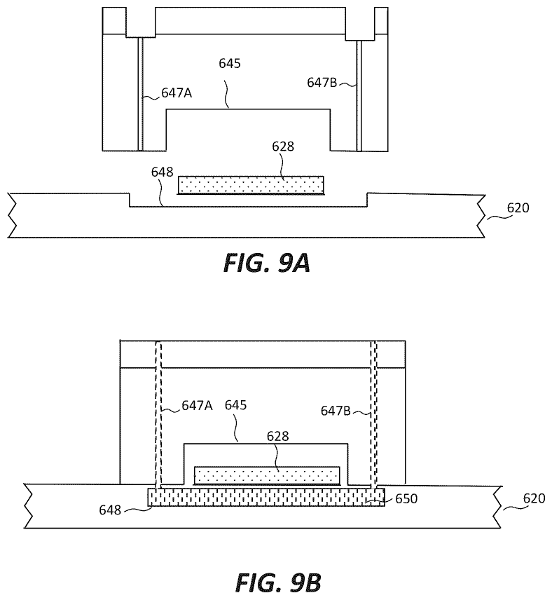

In certain embodiments, recesses in the stamp can allow stamp to contact only the bottom of a cavity. Micro-molding stamps may be used to seal cavities of any geometry by adhering to the top surface of the substrate. FIGS. 9A and 9B illustrate micro-molded getters in cavity in accordance with an embodiment. The microelectronic device substrate 620 can have a cavity 648. The cavity 648 can have a variety of geometries such as (but not limited to) rectangle, square, half sphere, ellipse, and irregular shapes. Functional elements 628 can be located on a suspended bridge and/or cantilever, and can be situated at least partially above the cavity 648. Stamps have recessed areas 645 to avoid direct contact with functional elements. Inks containing getter materials can be pumped into the cavity 648 via inlet 647A and outlet 647B. The cavity can be filled with getter material upon curing the ink, thereby forming a getter 650. During curing, the device cavity in combination with the stamp act as a mold for forming the getters. In this way, getter materials can be deposited into cavities that are located below functional element 628. In some embodiments, a plurality of holes can be formed in the device substrate via processes such as (but not limited to) etching through the substrate. The holes are open to the cavity. Nanoparticle ink can be filled through the holes to fill the cavity. In such embodiments, micro-molding stamps may have inlet channels and outlet channels whose positions can be aligned with the holes.

Although FIGS. 7 through 9B illustrate micro-molding stamps with recessed areas for fabricating getters at various locations of microelectronic devices, any systems and methods for micro-molding stamps and getter fabrication can be utilized as appropriate depending on the specific requirements of the given application.

### DOCTRINE OF EQUIVALENTS

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

As used herein, the singular terms “a,” “an,” and “the” may include plural referents unless the context clearly dictates otherwise. Reference to an object in the singular is not intended to mean “one and only one” unless explicitly so stated, but rather “one or more.”

As used herein, the terms “approximately” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to +10% of that numerical value, such as less than or equal to +5%, less than or equal to +4%, less than or equal to +3%, less than or equal to +2%, less than or equal to +1%, less than or equal to +0.5%, less than or equal to +0.1%, or less than or equal to +0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

What is claimed is:

1. A microelectronic device or a microelectromechanical system (MEMS) device comprising:
a first substrate;
at least one functional element disposed on the first substrate; and
a getter system disposed on a second substrate in proximity to the at least one functional element, the getter system comprising a plurality of getters, each getter comprising a plurality of nanoparticles;
wherein each of the plurality of getters has an aspect ratio between 0.05 and 10; and
wherein the getter system covers a surface area less than or equal to 90% of the second substrate.

2. The device of claim 1, wherein the at least one functional element is etched into the first substrate.

3. The device of claim 1, wherein the plurality of getters forms a pattern selected from the group consisting of: a grid of lines, a plurality of the grids, a patch of connected shapes, and a plurality of the patches; wherein at least one of the connected shapes is selected from the group consisting of: a strip, a polygon, and an oval.

4. The device of claim 1, wherein each of the getters has a width that is parallel to the second substrate between 10 microns and 500 microns, and a height that is perpendicular to the second substrate between 5 microns and 500 microns.

5. The device of claim 1, wherein the first substrate and the second substrate are the same substrate that is a surface of a wafer.

6. The device of claim 1, wherein the second substrate is an intermediate layer deposited on the first substrate.

7. The device of claim 1, wherein the second substrate is a surface of a capping wafer, and the first substrate is a surface of a wafer.

8. The device of claim 1, wherein the second substrate is a surface of a cavity or a ledge located on a capping wafer, and the first substrate is a surface of a wafer.

9. The device of claim 1, wherein the second substrate is a surface of a cavity, and the first substrate suspends above the second substrate.

10. The device of claim 1, wherein the microelectronic or the MEMS device is selected from the group consisting of: a gyroscope, an accelerometer, an oscillator, a chip-scale atomic clock, a digital micro-mirror device (DMD), a spatial light modulator (SLM), a pressure sensor, a laser, an inertial measurement units (IMU), a microbolometer, a quantum device, and a superconducting qubit.

11. The device of claim 1, wherein the nanoparticles are selected from the group consisting of metal nanoparticles, metal-oxide nanoparticles, and metal alloy nanoparticles.

12. The device of claim 1, wherein the nanoparticles comprise at least one element selected from the group consisting of: zinc, aluminum, yttrium, lanthanum, iron, molybdenum, niobium, tungsten, tantalum, manganese, titanium, zirconium, tin, nickel, chromium, cerium, platinum, gold, and cobalt.

13. The device of claim 1, wherein the nanoparticles comprise at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxides.

14. The device of claim 1, wherein the nanoparticles comprise at least one element selected from the group consisting of: zinc, aluminum, yttrium, lanthanum, iron, molybdenum, niobium, tungsten, tantalum, manganese, titanium, zirconium, tin, nickel, chromium, cerium, platinum, gold, and cobalt; and wherein the nanoparticles comprise at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxides.

15. The device of claim 1, wherein the plurality of nanoparticles has an average diameter between 1 nm and 10 microns.

16. The device of claim 1, wherein each getter further comprises a filler material; wherein the filler material controls a pore size of the getter.

17. The device of claim 1, wherein the getter system absorbs at least one of gas species selected from the group consisting of water vapor, hydrogen, oxygen, carbon monoxide, carbon dioxide, nitrogen and a volatile organic compound.

18. The device of claim 1, further comprising multiple substrates of getters and each substrate is configured to form onto a previous substrate.

19. The device of claim 1, wherein the plurality of getters comprises a same material.

20. The device of claim 1, wherein the plurality of getters comprises different materials and each material is selected to capture a different gas species.

21. A method for micro-molding getters, comprising:
providing a substrate;
applying a stamp to the substrate, wherein the stamp comprises a plurality of channels disposed adjacent to the substrate;
dispensing a nanoparticle ink through the plurality of channels onto the substrate;
curing the nanoparticle ink in the plurality of channels to form a plurality of getters comprising the nanoparticle ink on the substrate;
removing the stamp;
sintering the plurality of getters; and
activating the plurality of getters.

22. The method of claim 21, wherein the nanoparticle ink comprises nanoparticles selected from the group consisting of metal nanoparticles, metal-oxide nanoparticles, and metal alloy nanoparticles.

23. The method of claim 21, wherein the nanoparticle ink comprises at least one element selected from the group consisting of: zinc, aluminum, yttrium, lanthanum, iron, molybdenum, niobium, tungsten, tantalum, manganese, titanium, zirconium, tin, nickel, chromium, cerium, platinum, and cobalt.

24. The method of claim 21, wherein the nanoparticle ink comprises at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxides.

25. The method of claim 21, wherein the nanoparticles comprise at least one element selected from the group consisting of: zinc, aluminum, yttrium, lanthanum, iron, molybdenum, niobium, tungsten, tantalum, manganese, titanium, zirconium, tin, nickel, chromium, cerium, platinum, and cobalt; and wherein the nanoparticles comprise at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxides.

26. The method of claim 21, wherein the nanoparticle ink comprises nanoparticles with an average diameter between 1 nm and 10 microns.

27. The method of claim 21, wherein the nanoparticle ink further comprises a filler material; wherein the filler material controls a pore size of the plurality of getters.

28. The method of claim 21, wherein the stamp further comprises a recessed area such that the stamp avoids contact with a functional element on the substrate.

29. The method of claim 21, wherein the curing comprises contacting the nanoparticle ink with a source selected from the group consisting of: heat, an electromagnetic radiation, a xenon flash, an infrared radiation, an ultraviolet radiation, and a laser radiation.

30. The method of claim 21, wherein the sintering occurs at a temperature between 80° ° C. and 550° C.

31. The method of claim 21, wherein the sintering occurs in an environment selected from the group consisting of: in air, in an inert gas, and in vacuum.

32. The method of claim 21, wherein the sintering comprises sintering the plurality of getters in an inert gas, followed by a second gas that chemically reduces surface material of the plurality of getters.

33. The method of claim 21, wherein the activating occurs at a temperature between 80° C. and 550° C. in vacuum, in an inert gas, or in air.

34. The method of claim 21, wherein the stamp further comprises a protrusion to form the plurality of getters in a cavity.
